(19) United States
(12) Patent Application Publication
(10) Pub. No.: US 2012/0182708 A1
(43) Pub. Date: Jul. 19, 2012

(54) ENCLOSURE FOR A CONDUCTOR OF ELECTRICITY, THE ENCLOSURE BEING PROVIDED WITH CURRENT SENSORS

(75) Inventors: Patrice Juge, Marcellaz Albanais (FR); Guillaume Granelli, Seez (FR)

(73) Assignee: ALSTOM TECHNOLOGY LTD., BADEN (CH)

(21) Appl. No.: 13/392,695

(22) PCT Filed: Sep. 24, 2010
(86) PCT No.: PCT/EP10/64123

§ 371 Date: Feb. 27, 2012

(30) Foreign Application Priority Data
Sep. 25, 2009 (FR) 09 56651

(51) Int. Cl. H05K 5/06; H05K 5/00

(52) U.S. Cl. 361/807; 174/520; 174/50.5

(57) ABSTRACT

A characteristic enclosure, configured to surround a linear conductor, includes at least one internal cavity for receiving at least one fiber optic sensor or current transformer sensor wound about the enclosure and giving a measurement of current. The cavity is closed except at openings of small size in the outer wall through which the sensors are inserted, or are removed to replace them, and through which they are connected to a measuring apparatus. The enclosure includes grooves arranged on its surface or in separate tubes for guiding and maintaining loops of the sensors. Advantageously, one of the walls of the enclosure extends the walls of the adjacent enclosures for a regular flow of current induced along the enclosure.

The invention relates to an electricity conductor enclosure provided with current sensors, and that can be used in electrical apparatus that is another aspect of the invention.

Certain pieces of medium- or high-voltage electrical apparatus such as metal-enclosed substations or gas-insulated switchgear (GIS) include a linear conductor and a rigid enclosure filled with an insulating gas that surrounds the apparatus at a distance, while also supporting it by means of insulating spacers in the form of disks. The electrical apparatus is provided with various sensors, including current sensors that are suitable for being placed on the enclosure and that measure the flow of a current in the conductor by using electrical induction or the Faraday effect, depending on whether the sensing element of the sensor is another electrical conductor or an optical fiber. In both situations, sensors of that kind are wound about the enclosure to form at least one loop so as to pick up sufficient signal, and measuring equipment is connected to at least one end thereof.

Since the sensors are most frequently housed in a casing mounted on the inside face of the enclosure, the need for a connection requires the enclosure to be pierced, but that presents the drawback of making it more difficult to seal the enclosure. Another drawback that is often observed is that installing the sensor leads to considerable discontinuities in the section of the enclosure, which leads to disturbances in the high-frequency return currents that appear in particular when apparatus is switching, and which can thus give rise to electromagnetic radiation that falsifies the measurements of the sensors, or to arcing, thus damaging the insulating gas in the enclosure.

Finally, a general drawback of sensors mounted inside the enclosure is that they require the enclosure to be disassembled if the sensors need replacing, and that is unfortunate since, among other constraints, the toxic and polluting insulating gas inside the enclosure must be prevented from being released; whereas if sensors are installed outside the enclosure, as has been done in certain known designs, either the apparatus is made more bulky because of a casing in which the sensors are protected, or else the sensors are left bare and exposed to damage.

Document U.S. Pat. No. 5,136,236 describes a characteristic setup for such sensors. Document EP-A-1 710 589 describes another setup, in which the sensors are housed inside the enclosure in grooves of a segment of the enclosure, the grooves opening out into the plane faces of the segment ends, touching the segments in the vicinity of the enclosure: complete disassembly of the enclosure is necessary for the sensors. Document U.S. Pat. No. 4,320,337 describes a setup of sensors outside the enclosure. Document GB-A-2 332 784 describes a setup in which the sensors are mounted on a coil installed around the conductor, without contact with the enclosure: that design does not avoid the drawbacks of having to disassemble the enclosure in order to replace the sensors, and it may be assumed that measuring the sensor signal through an entire radius of the apparatus is problematic.

The enclosure of the invention is free from the above drawbacks: it enables easy installation and replacement of the sensor(s) and it does not disturb the flow of currents in the enclosure, nor the sealing of the enclosure.

In a general form, the invention provides an electricity conductor enclosure, the enclosure being rigid and distant from the electricity conductor that it surrounds, the enclosure being characterized in that it includes a circular cavity provided with at least one opening to an outside face, the cavity being occupied by at least one guide groove for guiding a filiform current sensor for sensing the current of the conductor, the groove including at least one loop and opening out into the opening.

The enclosure may include a plurality of such openings and such grooves, each of the grooves opening out into a respective opening, the openings preferably being offset angularly about the enclosure both in order to better distinguish the sensors and in order to gain more space for the measuring devices.

This design makes it possible to protect the sensor(s) between two concentric walls of the enclosure, by ensuring that the sensor(s) is/are properly positioned by being guided in the groove. The outer wall includes the opening for installing the sensor, but the inner wall remains continuous, thereby preserving sealing. The measurement end of the sensor remains accessible through the opening. The only additional bulkiness needed for the sensor corresponds to the measurement casing. Electrical disturbances are reduced providing the enclosure that houses the sensor does indeed extend the other enclosures by being of similar radial dimensions.

The groove may be established on a face of the cavity, or in a tube that is fastened to the cavity. In any event, the groove may be made of a material presenting friction that is lower than a preponderant material (metal) of the enclosure, in order to make assembly and disassembly easier.

The enclosure may be assembled as an extension of other conductor enclosures that are smooth, i.e. devoid of cavities. The enclosure is advantageously made up of two parts each of which is provided with a respective flat flange for fastening to one of the other enclosures and with a respective spacer, the spacers being concentric, being joined to the flange of the same part, and being provided with mutual centering faces, the cavity extending between the spacers, one of the spacers extending the smooth enclosures and coming directly into abutment against the flange of the other part, the other spacer having a radius different from the radius of the smooth enclosures and coming into abutment against the flange of the other part via a sealing gasket that is electrically insulating. The apparatus may include a plurality of such filiform sensors housed in the groove of the cavity, including an fiber optic sensor and a current transformer sensor that are united, which can improve measurement quality.

The disturbance to the shape of the general enclosure is thus negligible, as are the irregularities caused to the currents.

The invention is described below with reference to the following figures:

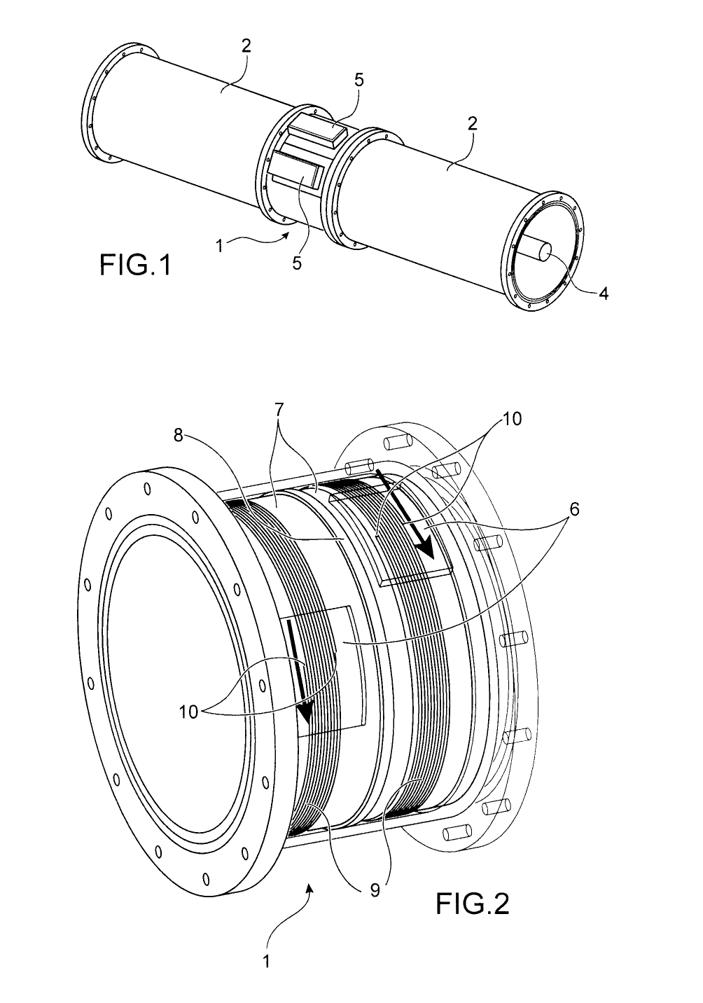

FIG. 1 is a general view of an embodiment of the invention;

FIG. 2 is a first view of an embodiment of an electricity conductor enclosure of the invention;

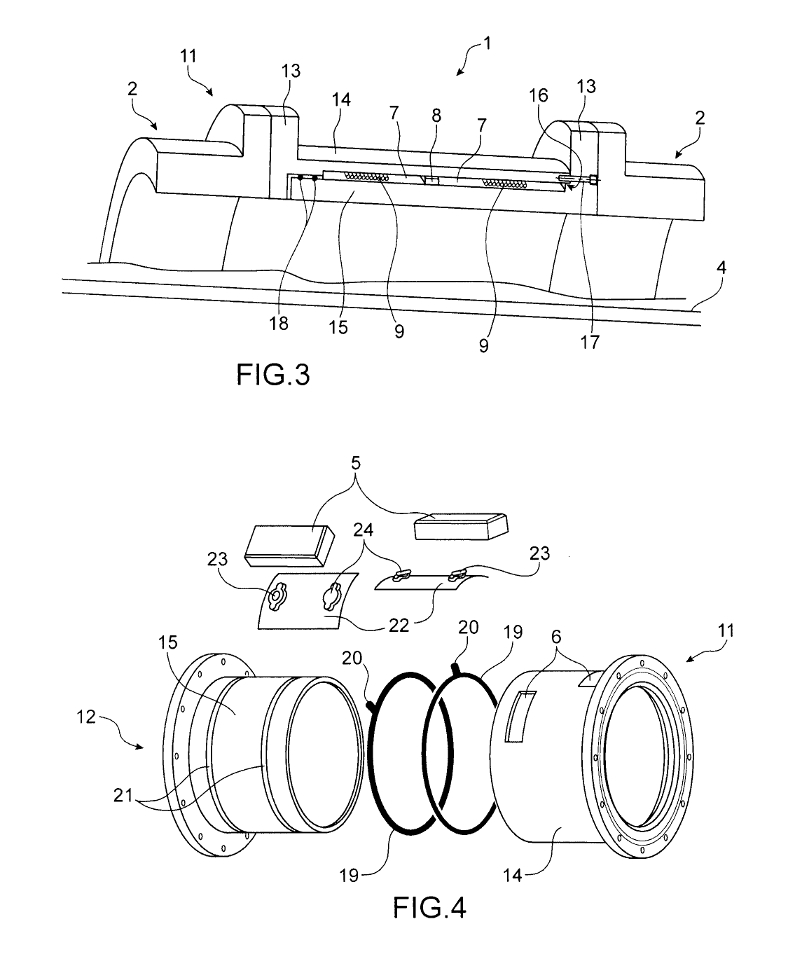

FIG. 3 is a second view;

FIG. 4 is an exploded view of another embodiment of the invention;

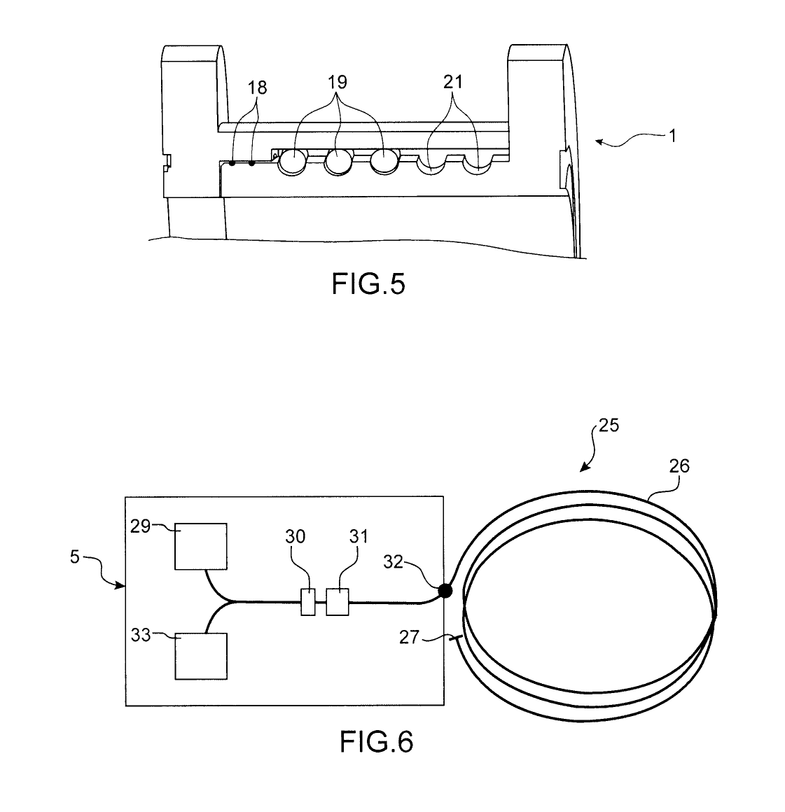

FIG. 5 shows a variant; and

FIG. 6 shows a sensor.

FIG. 1 is an outside view of a fraction of an enclosure for electrical apparatus such as a metal-enclosed substation or gas-insulated switchgear (GIS), in which the element that is characteristic of the invention is a central enclosure 1 that is shown attached by flanges to two other enclosures 2 that are cylindrical and smooth. A conductor 4 extends through the center of the enclosures 1 and 2 that insulate the conductor from the outside. The enclosure 1, that is used for holding the sensors may be shorter than the others. This embodiment shows an arrangement with two sensors, since the advantages of the invention are more obvious when a plurality of sensors are used, but it is entirely possible to use just one sensor. Since FIG. 1 is an outside view, all that can be seen are the measurement casings 5, which are mounted on the outside of the enclosure 1 at two angularly different locations, each occupying a major fraction of the length of the enclosure 1. If the casings 5 are removed, two openings 6 are uncovered that are offset both longitudinally and angularly in the enclosure 1, as shown in FIG. 2; the openings 6 lead to a cavity 7 inside the enclosure 1, which may either be shared by two openings, or else be divided by a rib 8, and in this embodiment the cavity 7 includes two tubes 9 that are wound about the enclosure 1, each forming a plurality of loops in this embodiment and that have ends 10 opening in a respective one of the openings 6. The tubes 9 serve to house the sensors, in this embodiment fiber optic sensors using the Faraday effect of the currents flowing through the conductor 4. The sensors are pushed into the tubes 9 through the openings at the ends 10, which tubes serve to guide the sensors and to keep them in a position that is favorable to taking measurements without allowing them to slide in the cavity 7. The limited angular and longitudinal extension of the openings 6, which extend over small portions of the enclosure 1, enables to protect the tubes 9 and also the sensors by the enclosure 1. The possibility to mount or replace the sensors with mere tucking movements avoid the need to ever dismount the enclosure 1. The tubes 9 are adhesively bonded or fastened in any other manner in the cavities 7. They are advantageously made of a material presenting friction that is lower than that of the material of the enclosure 1, e.g. they are made of polytetrafluoroethylene (PTFE). This makes it easy to insert the sensors, and also to remove them in order to replace them.

An appropriate current sensor 25 is shown in FIG. 6. It comprises an optical fiber 26 as the sensing element, with a mirror 27 at one end and the casing 5 at the other. The casing contains the elements that are necessary for using the sensor, namely a light source 29, a polarizer 30, an undulator 31, a circular polarizer 32, and a photodetector 33. The light emitted by the source 29 travels through the fiber 26 after passing through the elements 30 to 32, then returns to the photodetector 33 after being reflected by the mirror 27. The optical fiber 26 is wound in loops about the conductor 4, which is not shown here, but the current conveyed by the conductor affects the light traveling along the fiber in a way that can be measured.

Another view is shown in FIG. 3. The enclosure 1 is composed of two portions 11 and 12, each comprising a flange 13 and a spacer joined to the flange, respectively an outer spacer 14 and an inner spacer 15. The spacers 14 and 15 are concentric and the cavity 7 extends between them. The spacers 14 and 15 are assembled together via abutment surfaces 16 close to the flanges 13 so as to ensure mutual centering to preserve the concentricity of the spacers 14 and 15. The flange 13 of one of the parts is fastened to the spacer of the other part (in this embodiment the outer spacer 14) by means of screws 17. A sealing gasket 18 is provided at the junction between the other spacer 15 and the other flange 13. Advantageously, the gasket is also electrically insulating on condition that the smooth enclosures 2 extend (i.e. are in line with) the outer spacer 14, since the flow of return currents through the inner spacer 15 is thus hindered and these currents therefore flow in a manner that is regular and almost rectilinear through the enclosures 1 and 2, passing exclusively through the outer spacer, without any disturbance that would be responsible for radiation.

FIG. 4 shows an embodiment that is somewhat different and in which current transformers are used that operate using the Rogowski method. These sensors, given reference 19, are each in the form of a loop with a single turn that is closed at one end, where they are provided with terminals 20 for connection to the casings 5. Each sensor consists essentially of a conductor shaped to form windings stacked along the loop, with the ends of the conductor being connected to a terminal 20. Connection casings 5 for this kind of sensor obviously have contents that are adapted to sensitive electrical elements. Since such sensors are known, they are not described in further detail. Although it is possible to install them using tubes that are analogous to the tubes 9 (but having only a single loop), another implementation may be envisaged, relying on the use of grooves 21 cut into one of the spacers (in this embodiment the inner spacer 15), and providing the same guidance properties. Small cover plates 22 are also shown that are placed on the openings 6 and that have the connection casings 5 placed thereon. These small plates 22 may be similar, and each of them may be provided both with a boss 23 having an opening that is designed for allowing the connection terminal 20 to pass therethrough, and with a boss 24 that is continuous. Once the sensors 19 have been placed in the grooves 21 and their loops have been closed, the small plates 22 are placed on the outer spacer 14 while being turned in such a manner that the bosses 23 having openings face the openings 6 and the connection terminals 20. The connection casings 5 are thus fitted over the bosses 23 and 24 and the connection terminals 20. A tight assembly is obtained, by using a fastening collar that surrounds the connection casings 5 tightly, or by using any other tightening means on the connection terminals 20.

In this embodiment also, the grooves 21 may be coated in a low friction material in order to facilitate inserting the sensors 19.

A variant embodiment is shown in FIG. 5: each inner spacer 15 is provided with grooves 21 that are placed at regular intervals, in this embodiment there are five grooves, some of which are supernumerary, only three sensors 19 being installed in this embodiment. This design makes it possible to add new sensors during the lifespan of the apparatus, if so required. This poses no problem with the openings 6 that are all placed in different angular locations.

The tube devices and groove devices are not necessarily associated respectively with fiber optic sensors and with current transformer sensors.

A similar design to that shown in FIG. 5 could be adopted with fiber optic sensors. The number of loops in the sensors is not critical for good implementation of the invention: it is sufficient to provide suitable guiding and receiving devices.

Finally, the sensors of both categories may be placed together on a common enclosure 1, which may even be very advantageous for the reliability of measurements.

1-9. (canceled)

10. An electricity conductor enclosure, being rigid and distant from an electricity conductor that it surrounds, the enclosure comprising:
two parts fastened one to the other;
two flanges for fastening to other enclosures and with two spacers that extend between the flanges, the spacers being concentric;
a circular cavity constituting an interval between the spacers, wherein one of the spacers is an internal spacer being continuous to preserve sealing of the enclosure and another one of the spacers is an external spacer including at least one opening, having a limited angular extension, for installing a filiform current sensor for sensing current of the conductor, the cavity being occupied by at least one guide groove for guiding the sensor when pushing the sensor, the groove including at least one loop and opening out into the opening.

11. An electricity conductor enclosure according to claim 10, wherein the cavity includes a plurality of openings and a plurality of grooves, each of the grooves opening out into a respective opening, the openings being offset angularly about the enclosure.

12. An electricity conductor enclosure according to claim 10, wherein the groove is established on a face of the cavity.

13. An electricity conductor enclosure according to claim 10, wherein the groove is established in a tube that is fastened to the cavity.

14. An electricity conductor enclosure according to claim 10, wherein the groove is made of a material presenting friction that is lower than a preponderant material of the enclosure.

15. An electrical apparatus including an enclosure according to claim 10, assembled between other conductor enclosures that are smooth.

16. An electrical apparatus according to claim 15, wherein the two parts each includes one of the flanges and one of the spacers, the spacers including mutual centering faces, one of the spacers extending the other enclosures and coming directly into abutment against the flange of the other part, the other one of the spacers coming into abutment against the flange of the other part via a sealing gasket that is electrically insulating.

17. An electrical apparatus according to claim 15, including a plurality of filiform current sensors for sensing the current of the conductor, housed in the guide groove of the enclosure cavity.

18. An electrical apparatus according to claim 17, wherein the sensors include an fiber optic sensor and a current transformer sensor.

19. An electrical apparatus according to claim 16, including a plurality of filiform current sensors for sensing the current of the conductor, housed in the guide groove of the enclosure cavity.

20. An electrical apparatus according to claim 19, wherein the sensors include an fiber optic sensor and a current transformer sensor.
